(19) United States
(12) Patent Application Publication
(10) Pub. No.: US 2019/0084093 A1
(43) Pub. Date: Mar. 21, 2019

(54) BONDING MATERIAL

(71) Applicants: TOYOTA JIDOSHA KABUSHIKI KAISHA, Toyotak-shi (JP); Hitachi Chemical Company, Ltd., Tokyo (JP)

(72) Inventors: Masahiro SAKATA, Nisshin-shi (JP); Masaki YAMAGUCHI, Tsukuba-shi (JP); Koichi SAITOU, Tokyo (JP); Masaki TAKEUCHI, Tsukuba-shi (JP); Fumitaka UENO, Tsukuba-shi (JP); Katsuhiko YASU, Tokyo (JP)

(73) Assignees: TOYOTA JIDOSHA KABUSHIKI KAISHA, Toyota-shi (JP); Hitachi Chemical Company, Ltd., Tokyo (JP)

(21) Appl. No.: 16/127,464

(22) Filed: Sep. 11, 2018

(30) Foreign Application Priority Data
Sep. 21, 2017 (JP) 2017-181702

(51) Int. Cl. B23K 35/02; B23K 35/362; B23K 35/36; B23K 35/26; B23K 35/28; B23K 35/30

(52) U.S. Cl. CPC B23K 35/0244; B23K 35/362; B23K 35/3613; B23K 35/262; B23K 35/288; H01L 24/81; B23K 35/3006; B23K 35/3013; H01L 2224/81815; H01L 2224/83815; B23K 35/302

(57) ABSTRACT

A bonding material disclosed in this specification contains high melting point metal particles, low melting point metal particles, and a thermosetting flux resin. A mass proportion of the high melting point metal particles with respect to a total mass of the high melting point metal particles and the low melting point metal particles is 55% to 75%.

### INCORPORATION BY REFERENCE

The disclosure of Japanese Patent Application No. 2017-181702 filed on Sep. 21, 2017 including the specification, drawings and abstract is incorporated herein by reference in its entirety.

### BACKGROUND

### 1. Technical Field

The technology disclosed in this specification refers to a bonding material, and particularly, a bonding material that is unlikely to cause the occurrence of whiskers.

### 2. Description of Related Art

A bonding material (solder material) obtained by mixing metal particles with a high melting point such as copper (Cu) and metal particles with a low melting point such as a tin alloy (Sn alloy) is known (for example, Japanese Unexamined Patent Application Publication No. 2002-254194 (JP 2002-254194 A) and Japanese Unexamined Patent Application Publication No. 2002-261105 (JP 2002-261105 A)). Such a bonding material is suitable for a transient liquid phase sintering method (TLPS). The above bonding material is used for a primary reflow in mounting processes in which two reflow processes are necessary, such as mounting of a semiconductor module on a board.

### SUMMARY

When a bonding material is used, mitigation of whiskers is an issue. The technology disclosed in this specification provides a bonding material through which it is possible to suppress the occurrence of whiskers by limiting a blending ratio between high melting point metal particles and low melting point metal particles and blending in a thermosetting flux resin.

An aspect of the present disclosure relates to a bonding material containing high melting point metal particles, low melting point metal particles, and a thermosetting flux resin. A “high melting point metal” refers to a metal having a higher melting point than a “low melting point metal.” Here, particularly, the high melting point metal may have a higher melting point than an Sn—Ag—Cu bonding material. A “low melting point metal” refers to a metal having a lower melting point than a “high melting point metal.” A mass proportion of high melting point metal particles with respect to a total mass of high melting point metal particles and low melting point metal particles is 55% to 75% (thus, a mass proportion of low melting point metal particles is 45% to 25%).

According to the above mass proportions and blending in of the thermosetting flux resin, all of an Sn component which causes whiskers are used for alloying with a high melting point metal, and there is no remaining Sn component after reflowing. Therefore, it is possible to suppress the occurrence of whiskers. When a mass proportion of high melting point metal particles is less than 55%, the low melting point metal remains after sintering. The remaining low melting point metal causes the occurrence of whiskers. On the other hand, when a mass proportion of high melting point metal particles exceeds 75%, alloying does not proceed in the entire bonding material, and there is a risk of the bonding strength being insufficient. Here, a mass proportion of high melting point metal particles is preferably 65% to 75%. In such a range, the balance between a whisker mitigating effect and the bonding strength is favorable. In examples, results of tests in which a whisker mitigating effect is confirmed are shown.

Details and further improvement of the technology disclosed in this specification will be described in the following “detailed description of embodiments.”

### BRIEF DESCRIPTION OF THE DRAWINGS

Features, advantages, and technical and industrial significance of exemplary embodiments of the disclosure will be described below with reference to the accompanying drawings, in which like numerals denote like elements, and wherein:

FIG. 1 is an image diagram of a bonding material (before sintering);

FIG. 2 is an image diagram of a bonding material (after sintering);

FIG. 3A is a diagram for explaining a component mounting process using a bonding material and is a diagram for explaining a printing process of a paste-like bonding material;

FIG. 3B is a diagram for explaining a component mounting process using a bonding material and is a diagram for explaining a component loading process;

FIG. 3C is a diagram for explaining a component mounting process using a bonding material and is a diagram for explaining a reflow process;

FIG. 4 is a table showing results of a bonding material evaluation test; and

FIG. 5 is a table showing results of a bonding material evaluation test.

### DETAILED DESCRIPTION OF EMBODIMENTS

A bonding material disclosed in this specification is a conductive bonding material that is obtained using a transient liquid phase sintering method and can be sintered by performing reflowing at a temperature of 260° C. or lower. After sintering, the bonding material does not re-melt at 260° C. and can suppress the occurrence of whiskers. According to the bonding material disclosed in this specification, it is possible to lower a primary reflow temperature as compared to that of the related art. In addition, the bonding material disclosed in this specification can suppress the occurrence of whiskers. That is, even if it is left for a long time after sintering, conductive whiskers do not occur. Therefore, an insulation method such as applying a coating agent such as an insulating resin on a surface of an alloy after sintering is unnecessary.

Technical elements of the bonding material disclosed in this specification are as follows. Here, the following technical elements are independent technical elements, and exhibit technical usefulness alone or in various combinations.

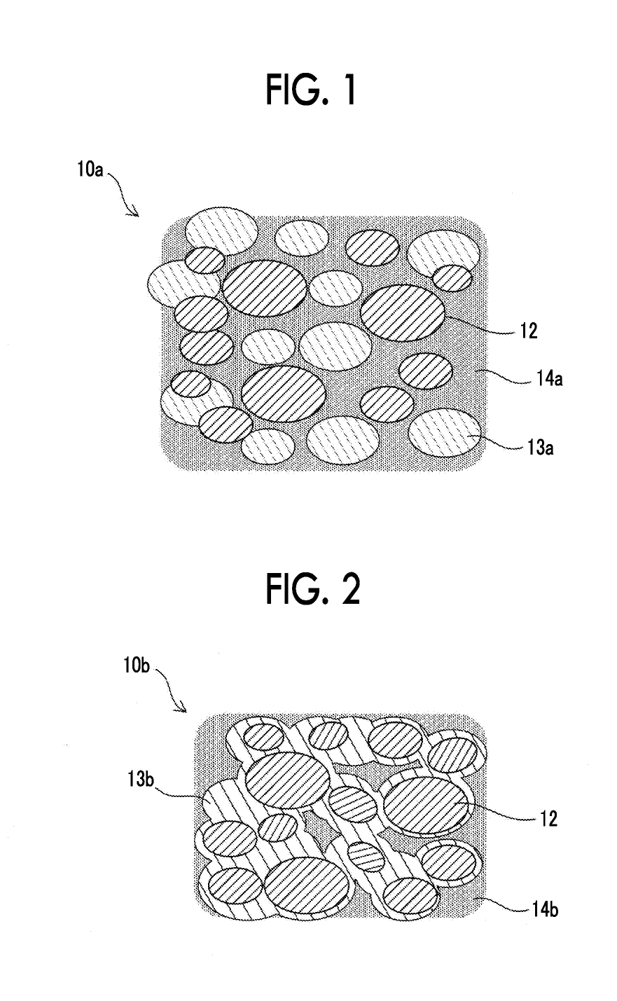

Images of a composite material disclosed in this specification are shown in FIG. 1 and FIG. 2. FIG. 1 is an image diagram of a bonding material 10a before sintering and FIG. 2 is an image diagram of a bonding material 10b after sintering. The bonding material 10a before sintering contains high melting point metal particles 12, low melting point metal particles 13a, and a thermosetting flux resin 14a. The high melting point metal particles 12 are, for example, Cu particles having a particle size of 5 μm to 15 μm. The low melting point metal particles 13a are, for example, Sn alloy particles having a particle size of 20 μm to 40 μm. A mass proportion of the high melting point metal particles 12 with respect to the total mass of the high melting point metal particles 12 and the low melting point metal particles 13a is, for example, 65%. The flux resin 14a has fluidity, and contains the high melting point metal particles 12 and the low melting point metal particles 13a. Since the flux resin 14a has fluidity, the bonding material 10a before sintering is paste-like.

In the bonding material after sintering (FIG. 2), the low melting point metal particles are melted and are alloyed with some of the high melting point metal particles. A hardened alloy 13b covers all of the residual particles of the high melting point metal and the bonding material 10b after sintering is sintered. In addition, a flux resin 14b is thermally cured. Since the entire low melting point metal (the low melting point metal particles 13a in FIG. 1) which causes whiskers is used for alloy, whiskers do not occur.

The high melting point metal particles may be a metal (metal alloy) having a higher melting point than an Sn—Ag—Cu bonding material. The high melting point metal particles may be any of Cu, a Cu alloy, Al, Ag, and Au, and may have a particle size of 5 μm to 35 μm. The high melting point metal particles are particularly desirably Cu particles. In addition, when the particle size is less than 5 μm, a aggregating force of particles increases, and when a bonding material paste is prepared, the viscosity may become higher. On the other hand, when the particle size exceeds 30 μm, since the metal density in the bonding material decreases, the bonding strength may be insufficient. Here, in the bonding material disclosed in this specification, as the high melting point metal particles, only any one type of metal from Cu, a Cu alloy, Al, Ag, and Au may be contained or metals of a plurality of types may be contained. The surface of the high melting point metal particles may be plated with Sn or an Sn alloy.

The low melting point metal particles may be an Sn alloy, and are desirably a medium temperature type to low temperature type solder material such as an Sn—Ag type material, an Sn—Ag—Cu type material, an Sn—In—Ag—Bi type material, an Sn—Zn type material, an Sn—Zn—Bi type material, an Sn—Bi type material, and an Sn—In type material. The bonding material disclosed in this specification may contain only one type of Sn alloy or contain Sn alloys of a plurality of types regarding the low melting point metal particles.

Desirably, the low melting point metal particles are an Sn alloy and have a particle size of 20 μm to 40 μm. When the particle size is less than 20 μm, wet spreadability (wettability) with respect to the high melting point metal particles deteriorates and there is a possibility of a high melting point metal that appears on the surface of the bonding material after reflowing not being covered. As a result, defective bonding may occur. When the particle size exceeds 40 μm, the accuracy may reduce when the bonding material is printed on a board.

A flux resin blended into the bonding material may include a thermosetting epoxy resin. In particular, as the flux resin, a resin in which an epoxy resin, an active agent, a rosin, a thixotropic agent, a solvent, and the like are uniformly mixed is preferably used. In addition, in addition to the above, a curing accelerator, an antioxidant, a powder surface treatment agent, a coupling agent, and the like may be included, and there is preferably in a range of 0.01 mass % to 5.0 mass % of these with respect to a resin composition of the flux resin.

The epoxy resin is not particularly limited, and for example, a bisphenol A type, a bisphenol F type, a biphenyl type, a naphthalene type thereof, and the like can be used. The epoxy resin is preferably a liquid at room temperature. When a solid epoxy resin is used, it is preferably combined with a liquid epoxy resin.

The active agent is not limited as long as it has an action of removing a metal oxide present on a surface of a metal. However, an organic acid, a non-dissociative active agent containing a non-dissociative halogenated compound, and an amine-based active agent are preferable. As the organic acid, succinic acid, glutaric acid, adipic acid, picolinic acid, 6-methylpicolinic acid, 3-cyclopropylpicolinic acid, 5-butylpicolinic acid, 6-cyclobutylpicolinic acid, benzoic acid, 1,2-aminododecanoic acid, sebacic acid, diphenylacetic acid, 3,5-dibromosalicylic acid, p-anisic acid, and the like may be exemplified.

As the non-dissociative active agent containing a non-dissociative halogenated compound, for example, as described in Japanese Unexamined Patent Application Publication No. 2015-160234 (JP 2015-160234 A), a non-salt type organic compound in which halogen atoms are bonded by a covalent bond may be exemplified. The halogenated compound may be a compound formed by covalent bonds of single elements such as chlorine, bromine, and fluorine, for example, a chlorinated product, a bromide, and a fluoride, and may be a compound having covalent bonds of any two or all of chlorine, bromine and fluorine. In order to improve solubility in an aqueous solvent, such a compound preferably has a polar group such as a hydroxyl group or a carboxyl group, for example, a halogenated alcohol or a carboxyl halide. As the halogenated alcohol, for example, a brominated alcohol such as 2,3-dibromopropanol/2,3-dibromobutanediol/trans-2,3-dibromo-2-butene-1,4-diol/1,4-dibromo-2-butanol/tribromoneopentyl alcohol, a chlorinated alcohol such as 1,3-dichloro-2-propanol/1,4-dichloro-2-butanol, a fluorinated alcohol such as 3-fluorocatechol, and other similar compounds may be exemplified. As the carboxyl halide, a carboxyl iodide such as 2-iodobenzoic acid, 3-iodobenzoic acid, 2-iodopropionic acid, 5-iodosalicylic acid, and 5-iodoanthranilic acid, a carboxyl chloride such as 2-chlorobenzoic acid and 3-chloropropionic acid, a brominated carboxylic acid such as 2,3-dibromopropionic acid, 2,3-dibromosuccinic acid, and 2-bromobenzoic acid, and other similar compounds may be exemplified. One type of such active agents may be used alone or two or more types of these active agents may be used in a mixture.

As the amine-based active agent, the following active agents described in, for example, JP 2015-160234 A, may be exemplified. As the amine-based active agent, amines (a polyamine such as ethylenediamine), amine salts (an organic acid salt, or an inorganic acid salt (hydrochloric acid, sulfuric acid, hydrobromic acid, etc.)) of amines such as trimethylolamine, cyclohexylamine and diethylamine and an aminoalcohol, amino acids (glycine, alanine, aspartic acid, glutamic acid, valine, etc.), amide compounds, and the like may be exemplified. Specifically, diphenylguanidine hydrobromide, cyclohexylamine hydrobromide, diethylamine salts (hydrochlorides, succinic acid salts, adipates, sebacic acid salts, etc.), triethanolamine, monoethanolamine, and hydrobromides of such amines may be exemplified. One type of such active agents may be used alone or a mixture of two or more types of such active agents may be used.

The active agent is preferably mixed in in a range of 0.5 mass % to 10.0 mass % with respect to the composition of the flux resin. When the range is less than 0.5%, the wettability after the low melting point metal particles are dissolved deteriorates, and sintering properties tend to be insufficient. In addition, when the range exceeds 10 mass %, insulation properties of the flux composition tend to deteriorate.

The rosin is not particularly limited as long as it is a natural rosin such as a rosin having a carboxyl group or a polymerized rosin. For example, natural rosins such as abietic acid, neoabietic acid, palustric acid, pimaric acid, isopimaric acid, and dehydroabietic acid and polymerized rosins such as acrylated rosin, hydrogenated rosin, and maleated rosin are preferable. One type of such rosins may be used alone or a mixture of two or more types thereof may be used.

As the solvent, a water soluble solvent having a relatively high boiling point is preferably used. For example, the following solvents described in JP 2015-160234 A may be exemplified. As such solvents, a water-soluble solvent having a boiling point of 170° C. or higher is preferably used. As such solvents, for example, diethylene glycol, dipropylene glycol, triethylene glycol, hexylene glycol, hexyl diglycol, 1,5-pentanediol, methyl carbitol, butyl carbitol, 2-ethylhexyl diglycol (EHDG), octanediol, phenylglycol, diethylene glycol monohexyl ether, and tetraethylene glycol dimethyl ether may be exemplified. One type of such solvents may be used alone or a mixture of two or more types thereof may be used.

The antioxidant may be contained in the flux, and a phenolic antioxidant, a sulfur antioxidant, and the like may be exemplified. The phenolic antioxidant may be a phenolic antioxidant having a substituted or unsubstituted phenol group in a molecule or a phenolic antioxidant having a hindered phenol structure or half hindered phenol structure. As the sulfur antioxidant, a thioester antioxidant having sulfur and ester bonds in a molecule may be exemplified. One type of such antioxidants may be used alone or a mixture of two or more types thereof may be used.

Proportions of metal particles and the flux resin in the conductive bonding material paste can be selected from an appropriate range according to the composition and the particle size of the metal, the type of the flux resin, and the like. With respect to the mass of the entire paste (the entire bonding material), the proportion of the metal particles is preferably 85 mass % to 95 mass %, and particularly preferably 88 mass % to 93 mass %. When the proportion is less than 85 mass %, printed shape defects of the bonding material, sagging during heating, and the like occur. In addition, when the proportion exceeds 95 mass %, the metal particles may not be sufficiently mixed into the flux resin.

A component for surface mounting is preferably bonded to a printed board using the bonding material disclosed in this specification. As a material of the printed board, a material such as phenolic paper, epoxy glass, a polyimide, bismaleimide triazine, a liquid crystal polymer, a thermosetting resin such as polytetrafluoroethylene and polyether ether ketone, a ceramic, or a metal may be used. The component for surface mounting may be any of a chip component, a semiconductor component, and a small mounting component. Examples of the chip component include an electronic component such as a capacitor, a resistor, and a diode. Examples of the semiconductor component include a quad flat package (QFP), a thin small outline package (TSOP), a small outline package (SOP), a chip size package (CSP), and a ball grid array (BGA). Examples of the small mounting component include an aluminum electrolytic capacitor, a transistor, a trimmer, a relay, and a transformer.

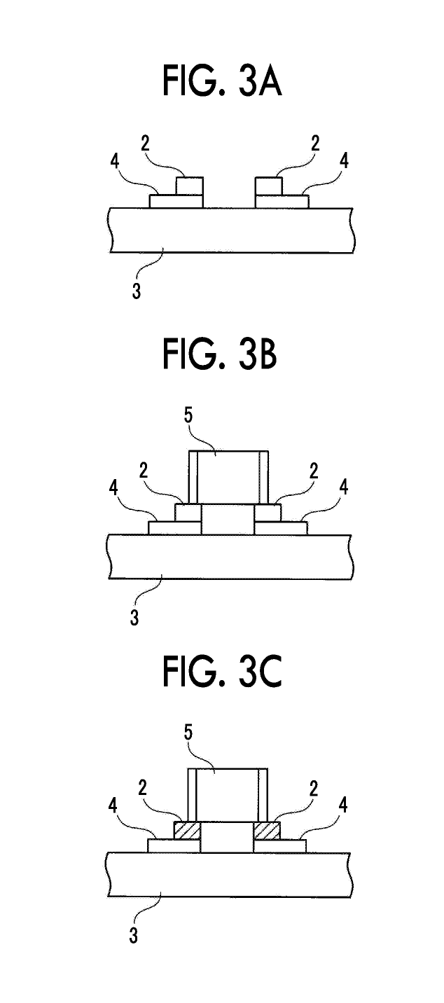

FIGS. 3A to 3C show diagrams for explaining a component mounting process using a bonding material disclosed in this specification. FIG. 3A is a diagram for explaining a process of printing a paste-like bonding material 2 on a circuit board 3. The conductive paste-like bonding material 2 is printed on a copper wiring 4 on the circuit board 3 using a metal mask or the like. FIG. 3B is a diagram for explaining a component loading process. A chip component 5 is mounted on the printed bonding material 2 by an electronic component mounting machine (chip mounter) or the like. FIG. 3C is a diagram for explaining a reflow process. FIG. 3C shows a board after reflow heating. When the circuit board 3 on which the chip component 5 is mounted is heated in a reflow furnace or the like, the bonding material 2 is alloyed, the entire material is solidified from a paste form, and the mounting is completed. Here, in FIG. 3C, in order to schematically represent that the bonding material 2 has changed from the state in FIG. 3B and alloyed, the bonding material 2 is illustrated with hatching.

When reflowing is performed twice and a component is mounted on a semiconductor module mounting board, a component built-in board, or the like, if the bonding material disclosed in this specification is used for the primary reflow, the following advantages are obtained.

(1) It is possible to mount a component at a lower temperature (260° C.) than in the related art.
(2) There is no re-melting during the secondary reflow (about 260° C.).
(3) A load on the environment is small (support Pb-free).
(4) No whiskers occur in junctions. Since no whiskers occur, there is no need to apply a coating agent such as an insulating resin to bonding parts after bonding.

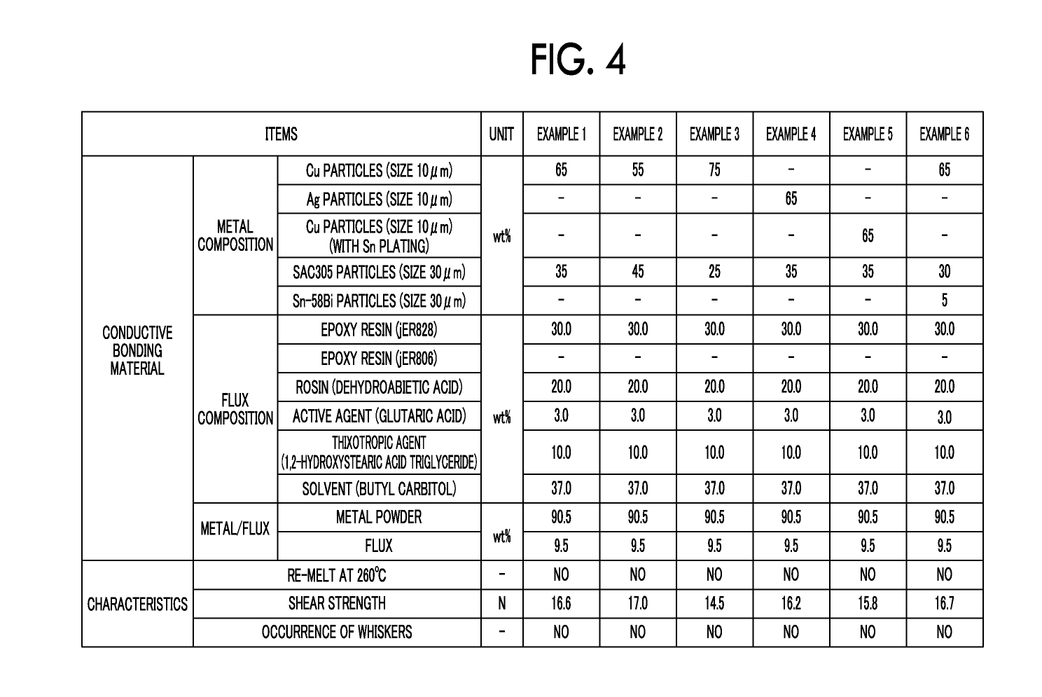

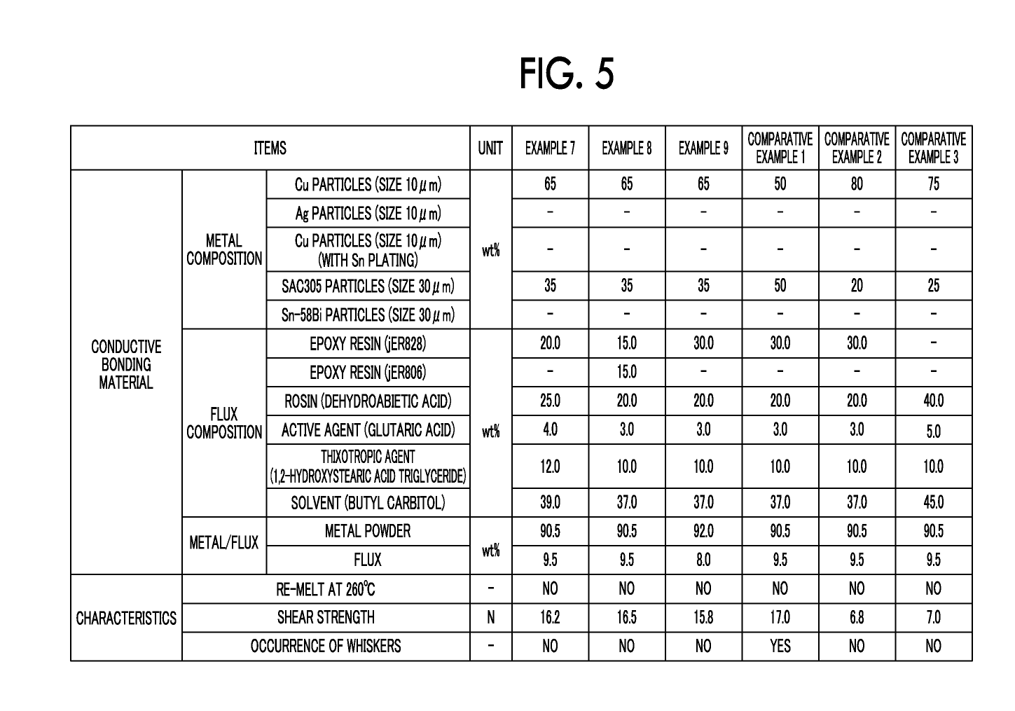

Examples will be described below. 9 types of evaluation sample and 3 types of comparative example were prepared with different formulations, and (1) whether re-melting occurred, (2) shear strength, and (3) the occurrence of whiskers were evaluated. Methods performed were as follows. FIG. 4 and FIG. 5 show compositions and evaluation results (characteristics) of Examples 1 to 9 and Comparative Examples 1 to 3.

<Preparation of Flux Resin> (Common Method)

A liquid epoxy resin (product name “jER828”/“jER806”, bisphenol A type/F type epoxy resin, commercially available from Mitsubishi Chemical Corporation), a rosin (dehydroabietic acid), an active agent (glutaric acid), a thixotropic agent (1,2-hydroxystearic acid triglyceride), and a solvent (butyl carbitol) were thoroughly mixed to prepare a flux resin.

<Preparation of Conductive Paste (Bonding Material)> (Common Method)

The flux resin, a commercially available copper powder (average particle size of 10 μm), and a solder powder (SAC305, average particle size of 30 μm) were kneaded with a softener to prepare a conductive paste bonding material. SAC305 is a solder material having an alloy composition of Sn-3.0Ag-0.5Cu.

### Preparation of Evaluation Samples (Examples and Comparative Examples)

On a glass epoxy board having a surface on which a copper foil land was formed, the above bonding material was printed with a metal squeegee using a 0.8 mm×1.5 mm×100 μm metal mask. Then, 20 Sn plated 1005 chips were placed on a printed film of a copper foil land. Chip components were mounted under reflow conditions of a preheat temperature of 180° C. and a peak temperature of 250° C., and were used as evaluation samples.

<Evaluation of Re-Melting at 260° C.>

The prepared evaluation samples were floated in a solder bath set at 260° C. for 1 minute, and it was visually observed whether the junction was re-melted.

<Evaluation of Shear Strength>

The shear strength of the chip junction of the prepared evaluation samples was measured using a shear tester (“Universal bond tester 4000” commercially available from Dage Japan).

<Evaluation of Occurrence of Whiskers>

The prepared evaluation samples were placed under high temperature and high humidity conditions of 85° C. and 85 RH for 200 hours, and were then left at room temperature for 24 hours. These were performed 5 times, and then it was observed whether whiskers occurred under a microscope. Repeating this under the above conditions five times corresponded to being left for 1000 hours at a high temperature and high humidity.

The technical significance of the compositions of Examples 1 to 9 and Comparative Examples 1 to 3 is as follows.

Example 1: reference composition (content of Cu particles: 65 wt %)
Example 2: lower limit of a mass proportion of Cu particles (content of Cu particles: 55 wt %)
Example 3: upper limit of a mass proportion of Cu particles (content of Cu particles: 75 wt %)
Example 4: Ag particles were used in place of Cu particles
Example 5: there was Sn plating on the surface of Cu particles
Example 6: mixed composition of solder powder SAC305 and Sn—Bi particles
Example 7: compositional proportion of the flux was changed
Example 8: two types of epoxy resin were mixed
Example 9: mixing proportions of metal and flux changed
Comparative Example 1: content of Cu particles was too small (content of Cu particles: 50 wt %)
Comparative Example 2: content of Cu particles was too large (content of Cu particles: 80 wt %)
Comparative Example 3: no epoxy resin

Evaluation results are shown in FIG. 4 and FIG. 5. Based on the results in FIG. 4 and FIG. 5, in Examples 1 to 9, no re-melting at 260° C. occurred and no whiskers occurred. In Examples 1 to 9, as the shear strength, a favorable strength of 14.6 to 17.0 [N] was obtained. Unlike these examples, in Comparative Example 1 in which a compositional proportion of Cu particles was 50 mass %, since the compositional proportion of Cu particles was low, the occurrence of whiskers due to the remaining solder material SAC305 (Sn) after reflowing was observed.

In addition, in Comparative Example 2 in which a compositional proportion of Cu particles was 80 mass %, since there was insufficient solder material SAC305, the shear strength significantly decreased. In addition, in Comparative Example 3 in which a proportion of Cu particles was relatively large, and no epoxy resin was contained in the flux composition, since the flux resin was not thermally cured, a decrease in the shear strength was observed.

Favorable results were obtained when a mass proportion of high melting point metal particles (Cu particles) in the total mass of high melting point metal particles (Cu particles) and low melting point metal particles (solder material SAC305) was 55% (Example 2) to 75% (Example 3). In particular, favorable results were obtained when a mass proportion of high melting point metal particles (Cu particles) was 65% (Examples 1, 4 to 9) to 75% (Example 3).

Points to be noted related to the technology described with reference to the examples will be described. The meanings of metal symbols described in the above description are as follows. Cu: copper, Sn: tin, Al: aluminum, Au: gold, Ag: silver, Bi: bismuth, In: indium, Zn: zinc.

While specific examples of the present disclosure have been described above in detail, these are only examples, and do not limit the scope of the claims. The technologies described in the scope of the claims include various modifications and alternations of the specific examples exemplified above. Technical elements described in the present specification or drawings exhibit technical usefulness alone or in various combinations, and are not limited to combinations described in the claims at the time of filing of this application. In addition, the technologies exemplified in this specification and drawings can achieve a plurality of objects at the same time, and have technical usefulness themselves when one object among them is achieved.

What is claimed is:

1. A bonding material comprising:
high melting point metal particles;
low melting point metal particles whose melting point is lower than a melting point of the high melting point metal particles; and
a thermosetting flux resin
wherein a mass proportion of the high melting point metal particles with respect to a total mass of the high melting point metal particles and the low melting point metal particles is 55% to 75%.

2. The bonding material according to claim 1, wherein the mass proportion of the high melting point metal particles is 65% to 75%.

3. The bonding material according to claim 1, wherein the high melting point metal particles are any of Cu, a Cu alloy, Al, Ag, and Au, and have a particle size of 5 μm to 30 μm.

4. The bonding material according to claim 1, wherein the low melting point metal particles are an Sn alloy and have a particle size of 20 μm to 40 μm.

5. The bonding material according to claim 1, wherein surfaces of the high melting point metal particles are plated with Sn or an Sn alloy.

6. The bonding material according to claim 1, wherein the flux resin includes an epoxy resin.
